(19) United States
(12) Patent Application Publication
(10) Pub. No.: US 2021/0363327 A1
(43) Pub. Date: Nov. 25, 2021

(54) STRETCHED FILM, CIRCULARLY POLARIZING PLATE, AND DISPLAY DEVICE

(71) Applicant: FUJIFILM Corporation, Tokyo (JP)

(72) Inventor: Hideyuki NISHIKAWA, Kanagawa (JP)

(73) Assignee: FUJIFILM Corporation, Tokyo (JP)

(21) Appl. No.: 17/394,085

(22) Filed: Aug. 4, 2021

Related U.S. Application Data
(63) Continuation of application No. PCT/JP2020/007664, filed on Feb. 26, 2020.

(30) Foreign Application Priority Data
Feb. 27, 2019 (JP) 2019-034120

(51) Int. Cl. C08K 5/55; C08G 64/06; C08G 64/28; C08J 5/18; C09B 57/00; G02B 1/08; G02B 5/20; G02B 5/30

(52) U.S. Cl. CPC C08K 5/55; C08G 64/06; C08G 64/28; C08J 5/18; C08J 2369/00; G02B 1/08; G02B 5/208; G02B 5/3025; C09B 57/00

(57) ABSTRACT

The present invention provides a stretched film exhibiting excellent reverse wavelength dispersibility, a circularly polarizing plate, and a display device. The stretched film of an embodiment of the present invention is a stretched film having a slow axis in an in-plane direction, in which the stretched film satisfies a relationship of Formula (A) Re(450)/Re(550)<1.00, and an absorption at a wavelength of 700 to 900 nm in a fast axis direction of the stretched film is larger than an absorption at a wavelength of 700 to 900 nm in a slow axis direction of the stretched film. In Formula (A) Re(450) represents an in-plane retardation of the stretched film at a wavelength of 450 nm and Re(550) represents an in-plane retardation of the stretched film at a wavelength of 550 nm.

### CROSS-REFERENCE TO RELATED APPLICATIONS

This application is a Continuation of PCT International Application No. PCT/W2020/007664 filed on Feb. 26, 2020, which claims priority under 35 U.S.C. § 119(a) to Japanese Patent Application No. 2019-034120 filed on Feb. 27, 2019. The above application is hereby expressly incorporated by reference, in its entirety, into the present application.

### BACKGROUND OF THE INVENTION

### 1. Field of the Invention

The present invention relates to a stretched film, a circularly polarizing plate, and a display device.

### 2. Description of the Related Art

A phase difference film having refractive index anisotropy (optically anisotropic film) has been applied to various uses such as an antireflection film of a display device, and an optical compensation film of a liquid crystal display device.

In recent years, an optically anisotropic film exhibiting reverse wavelength dispersibility has been studied (JP2008-273925A). In addition, the reverse wavelength dispersibility means “negative dispersion” characteristics showing an increase in a birefringence in accordance with an increase in a measurement wavelength in at least a part of a wavelength range in the visible region.

### SUMMARY OF THE INVENTION

On the other hand, a reverse wavelength dispersibility exhibited by optically anisotropic films in the related art has not necessarily been sufficient, and accordingly, a further improvement has been required.

More specifically, in a case of taking an example in which a λ/4 plate (¼ wavelength plate) is used as an optically anisotropic film, it is ideal that a phase difference in the visible region is a ¼ wavelength of a measurement wavelength. However, in optically anisotropic films in the related art, there is a tendency that a deviation from an ideal curve appears on a long wavelength side in the visible region. Furthermore, in the present specification, the optical characteristics (in-plane phase difference) which are closer to the ideal curve are meant to indicate that the reverse wavelength dispersibility is excellent.

In addition, a stretched film exhibiting excellent reverse wavelength dispersibility as described above has also been desired.

Taking the circumstances into consideration, the present invention has an object provide a stretched film exhibiting excellent reverse wavelength dispersibility.

In addition, the present invention has another object to provide a circularly polarizing plate and a display device.

The present inventors have conducted intensive studies on problems in the related art, and as a result, they have found that the objects can be accomplished by the following configurations.

(1) A stretched film having a slow axis in an in-plane direction,
in which the stretched film satisfies a relationship of Formula (A) which will be described later, and
an absorption at a wavelength of 700 to 900 urn in a fast axis direction of the stretched film is larger than an absorption at a wavelength of 700 to 900 nm in a slow axis direction of the stretched film.

(2) The stretched film as described in (1), comprising:
a polymer including a repeating unit having a residue derived from an infrared absorbing coloring agent; or
an infrared absorbing coloring agent and a polymer.

(3) The stretched film as described in (1) or (2),
in which the infrared absorbing coloring agent is a compound represented by Formula (1) which will be described later.

(4) The stretched film as described in any one of (1) to (3),
in which an in-plane retardation at a wavelength of 550 nm is 110 to 160 nm.

(5) A circularly polarizing plate comprising:
the stretched film as described in (4); and
a polarizer.

(6) A display device comprising:
a display element; and
the circularly polarizing plate as described in (5), arranged on the display element.

According to the present invention, it is possible to provide a stretched film exhibiting excellent reverse wavelength dispersibility.

In addition, according to the present invention, it is also possible to provide a circularly polarizing plate and a display device.

### BRIEF DESCRIPTION OF THE DRAWINGS

FIG. 1 is a view showing a comparison between the wavelength dispersion of an optically anisotropic film exhibiting reverse wavelength dispersibility in the related art and the wavelength dispersion of an ideal phase difference.

FIG. 2 is a view showing the wavelength dispersion characteristics with respect to a refractive index and an absorption coefficient of an organic molecule.

FIG. 3 is a view showing a comparison of the wavelength dispersion between an extraordinary ray refractive index ne and an ordinary ray refractive index no depending on the presence or absence of predetermined absorption characteristics.

### DESCRIPTION OF THE PREFERRED EMBODIMENTS

Hereinafter, the present invention will be described in detail. Furthermore, in the present specification, a numerical range expressed using “to” means a range that includes the preceding and succeeding numerical values of “to” as the lower limit value and the upper limit value, respectively.

First, terms used in the present specification will be described. In addition, a fast axis and a slow axis are each defined at 550 nm unless otherwise specified.

In the present invention, Re(λ) and Rth(λ) represent an in-plane retardation and a thickness-direction retardation at a wavelength of λ, respectively. The wavelength of refers to 550 nm unless otherwise specified.

In the present invention, Re(λ) and Rth(λ) are values measured at a wavelength of AxoScan OPMF-1 (manufactured by Opt, Science, Inc.). By inputting an average refractive index ((nx+ny+nz)/3) and a film thickness (d (μm)) to AxoScan, the values can be calculated:
Slow axis direction (°)

Re(λ)=R0(λ)

Rth(λ)=((nx+ny)/2−nz)×d.

Furthermore, R0(λ) is expressed in a numerical value calculated with AxoScan OPMF-1, but means Re(λ).

In the present specification, the refractive indices, nx, ny, and nz are measured with an. Abbe refractometer (NAR-4T, manufactured by Atago Co., Ltd.), using a sodium lamp (λ=589 nm) as a light source. In addition, in a case where a wavelength dependency is measured, the wavelength dependency can be measured with a multi-wavelength Abbe refractometer DR-M2 (manufactured by Atago Co., Ltd.) in combination with an interference filter.

Moreover, the values mentioned in Polymer Handbook (JOHN WILEY & SONS, INC.) and the catalogues of various optical films can be used. The values of the average refractive indices of major optical films are exemplified below: cellulose acylate (1.48), cycloolefin polymer (1.52), polycarbonate (1.59), polymethyl methacrylate (1.49), and polystyrene (1.59).

Moreover, in the present specification, “visible rays” are intended to mean a light at a wavelength of 400 nm or more and less than 700 nm. Further, “infrared rays” are intended to mean light at a wavelength of 700 nm or more, “near-infrared rays” are intended to mean light at a wavelength from 700 nm to 2,000 nm, and “ultraviolet rays” are intended to mean light at a wavelength of 10 nm or more and less than 400 nm.

In addition, in the present specification, angles (for example, an angle of “90°”) and a relationship thereof (for example, “perpendicular” and “parallel”) include a range of errors tolerable in the technical field to which the present invention belongs. For example, the angle means an angle in a range of less than ±10° of a rigorous angle, and the error from the rigorous angle is preferably 5° or less, and more preferably 3° or less.

The bonding direction of a divalent group (for example, —O—CO—) as noted in the present specification is not particularly limited, and for example, in a case where in the group represented by X-L-Y, L is —O—CO—, and *1 and *2 represent a bonding position to the X side and a bonding position to the Y side, respectively, L may be either *1-O—CO-*2 or *1-CO—O-*2.

As one of the feature points of the stretched film of an embodiment of the present invention, it may be mentioned that the absorption characteristics of the stretched film at a wavelength of 700 to 900 nm are controlled.

Hereinafter, features of the present invention will be described in detail. Furthermore, in the following, a stretched film exhibiting uniaxiality will be described as an example, but the stretched film of the embodiment of the present invention is not limited to the uniaxiality.

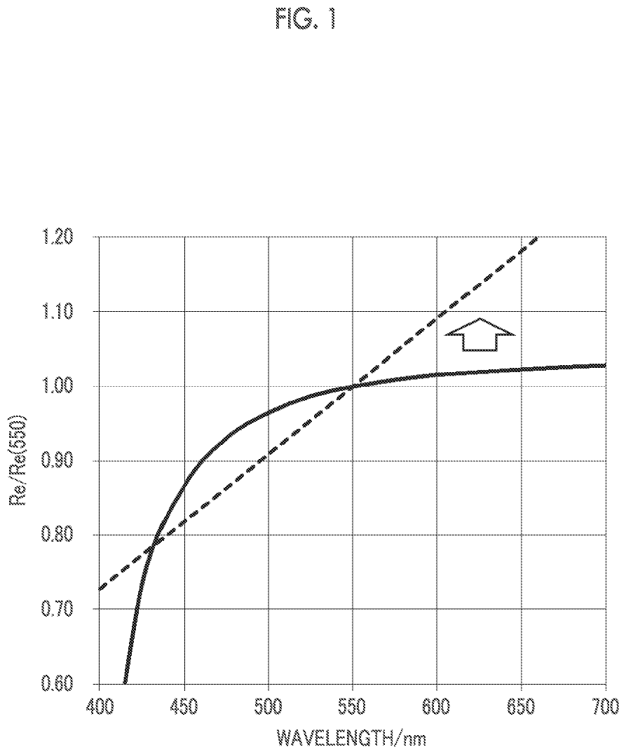

First, FIG. 1 shows the wavelength dispersion characteristics of a phase difference (Re(λ)) at each wavelength in the visible region with a phase difference (Re(550 nm)) at a measurement wavelength of 550 nm being normalized as 1. For example, the above-mentioned ideal λ/4 plate has “negative dispersion” characteristics in that a phase difference increases as a measurement wavelength increases since the phase difference is in a relationship in proportional with the measurement wavelength, as indicated by a dotted line in FIG. 1. In contrast, with regard to an optically anisotropic film exhibiting reverse wavelength dispersibility in the related art, the wavelength dispersion characteristics are at positions overlapping an ideal curve indicated by a dotted line in the short wavelength range but show a tendency to deviate from the ideal curve in the long wavelength range, as indicated by a solid line in FIG. 1.

In the stretched film of the embodiment of the present invention, it is possible to approximate the optical characteristics in the long wavelength range to the ideal curve as indicated by an outlined arrow by controlling the absorption characteristics at a wavelength of 700 to 900 nm of the stretched film.

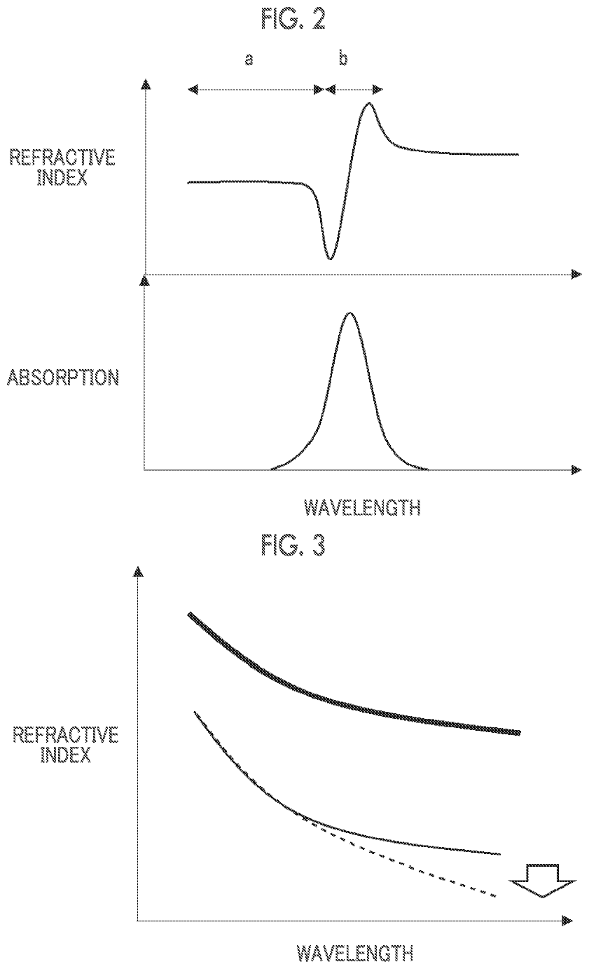

As a reason why the characteristics are obtained, the refractive index wavelength dispersion characteristics of general organic molecules will firstly be described with reference to FIG. 2. In FIG. 2, the upper side shows the behavior of a refractive index with respect to a wavelength, and the lower side shows the behavior (absorption spectrum) of absorption characteristics with respect to the wavelength.

For the organic molecule, a refractive index n in a region (a region a in FIG. 2) away from the intrinsic absorption wavelength decreases monotonically as the wavelength increases. Such the dispersion is referred to as “normal dispersion”. In contrast, a refractive index n in a wavelength band including an intrinsic absorption (a region b in FIG. 2) rapidly increases as the wavelength increases. Such the dispersion is referred to as “anomalous dispersion”.

That is, as shown in FIG. 2, an increase or a decrease in the refractive index is observed immediately before the wavelength range with the absorption.

In the stretched film of the embodiment of the present invention, the absorption at a wavelength of 700 to 900 nm in the fast axis direction is larger than the absorption at a wavelength of 700 to 900 nm in the slow axis direction. Hereinafter, such absorption characteristics are also referred to as absorption characteristics X. As described in detail later, it may be one of means for achieving the absorption characteristics X, for example, to arrange the axial direction having a high absorbance of the infrared absorbing coloring agent in the stretched film to be in parallel with the fast axis direction.

In the stretched film exhibiting the absorption characteristics X, the ordinary ray refractive index is further reduced, as compared with the stretched film not having the absorption characteristics X.

Specifically, FIG. 3 is a view showing a comparison of the wavelength dispersion between an extraordinary ray refractive index ne and an ordinary ray refractive index no depending on the presence or absence of the absorption characteristics X. In FIG. 3, the thick line indicates a curve of the extraordinary ray refractive index ne in the absence of the absorption characteristics X, and the solid line indicates a curve of the ordinary ray refractive index no in the absence of the absorption characteristics X. In contrast, in the stretched film of the embodiment of the present invention, having the absorption characteristics X, a value of the ordinary ray refractive index no in the long wavelength range in the visible region is further reduced as indicated by a broken line under the influence derived from an absorption at a wavelength of 700 to 900 nm as shown in FIG. 2. As a result, a birefringence Δn which is a difference between the extraordinary ray refractive index ne and the ordinary ray refractive index no is larger in the long wavelength range in the visible region, and thus, the behavior indicated by an arrow shown in FIG. 1 is accomplished.

Hereinafter, the configuration of the stretched film of the embodiment of the present invention (hereinafter also simply referred to as the “stretched film”) will be described in detail.

The stretched film has a slow axis in the in-plane direction. That is, the stretched film is a film exhibiting optical anisotropy in the in-plane direction.

The in-plane retardation (Re(550)) at a wavelength of 550 nm of the stretched film is not particularly limited, but from the viewpoint that the stretched film is useful as λ/4 plate, the in-plane retardation is preferably 110 to 160 nm, and more preferably 120 to 150 nm.

The stretched film satisfies a relationship of Formula (A). That is, it satisfies a ratio of Re(450) to Re(550) which is less than 1.00.

Re(450)/Re(550)<1.00 Formula (A)

Re(450) represents an in-plane retardation of the stretched film at a wavelength of 450 nm and Re(550) represents an in-plane retardation of the stretched film at a wavelength of 550 nm.

Among those, Re(450)/Re(550) is preferably 0.97 or less, more preferably 0.92 or less, and still more preferably 0.88 or less. A lower limit thereof is not particularly limited, but is often 0.75 or more.

Re(650)/Re(550) of the stretched film is not particularly limited, but is preferably 1.05 or more, more preferably 1.08 or more, and still more preferably 1.10 or more. An upper limit thereof is not particularly limited, but is preferably 1.25 or less, and more preferably 1.20 or less.

Re(650)/Re(550) is a ratio of Re(650) to Re(550).

In addition, Re(650) represents an in-plane retardation of the stretched film at a wavelength of 650 nm.

The thickness of the stretched film is not particularly limited, but is preferably 10 μm or less, more preferably 0.5 to 8.0 μm, and still more preferably 0.5 to 6.0 μm from the viewpoint of reducing the thickness.

Furthermore, in the present specification, the thickness of the stretched film is intended to mean an average thickness of the stretched film. The average thickness is obtained by measuring the thickness at any five or more points of the stretched film and determining an arithmetic mean of the values.

In the stretched film, the absorption at a wavelength of 700 to 900 nm in the fast axis direction of the stretched film (hereinafter also referred to as an “absorption F”) is larger than the absorption at a wavelength of 700 to 900 nm in the slow axis direction of the stretched film (hereinafter also referred to as an “absorption S”).

An expression, “the absorption F is larger than the absorption S”, is intended to mean that a maximum absorbance in a wavelength range of 700 to 900 nm of an absorption spectrum obtained upon irradiation of the stretched film with polarized light in parallel with the fast axis of the stretched film is larger than a maximum absorbance in a wavelength range of 700 to 900 nm of an absorption spectrum obtained upon irradiation of the stretched film with polarized light in parallel with the slow axis of the stretched film.

In addition, the measurement can be carried out using a spectrophotometer (MPC-3100 manufactured by SHIMADZU Corporation) equipped with a polarizer for infrared rays.

Moreover, the anisotropy of the absorption as described above can be realized, for example, by using an infrared absorbing coloring agent as will be described later. In particular, it is possible to make the absorption F larger than the absorption S by using a dichroic infrared absorbing coloring agent to set the axial direction having a higher absorbance of the coloring agent to be in parallel with the fast axis direction of the stretched film.

<Suitable Aspect 1>

Materials included in the stretched film are not particularly limited as long as they satisfy the requirements, but one of suitable aspects of the stretched film may be a stretched film including a polymer (hereinafter also referred to as a “specific polymer”) including a repeating unit having a residue (hereinafter also simply referred to as an “infrared absorbing coloring agent residue”) derived from an infrared absorbing coloring agent.

The infrared absorbing coloring agent residue means a group obtained by removing any hydrogen atom from an infrared absorbing coloring agent, and for example, in a case where one hydrogen atom is removed, the residue serves as a monovalent infrared absorbing coloring agent residue, and in a case where two hydrogen atoms are removed, the residue serves as a divalent infrared absorbing coloring agent residue.

The molecular weight of the specific polymer is not particularly limited, but the weight-average molecular weight is preferably 5000 or more, and more preferably 10,000 or more. An upper limit thereof is not particularly limited, but is often 1,000,000 or less.

The infrared absorbing coloring agent capable of forming an infrared absorbing coloring agent residue may be a coloring agent having a maximum absorption wavelength in the infrared region.

The molecular weight of the infrared absorbing coloring agent is not particularly limited, but is preferably less than 5,000. A lower limit thereof is not particularly limited, but is often 500 or more.

Furthermore, in the present specification, the infrared absorbing coloring agent is a so-called low-molecular-weight compound, and the infrared absorbing coloring agent does not include a compound having a plurality of repeating units. That is, the specific polymer corresponds to a compound different from the infrared absorbing coloring agent (in other words, the specific polymer is not included in the infrared absorbing coloring agent).

Examples of the infrared absorbing coloring agent include diketopyrrolopyrrole-based coloring agents, diimmonium-based coloring agents, phthalocyanine-based coloring agents, naphthalocyanine-based coloring agents, azo-based coloring agents, polymethine-based coloring agents, anthraquinone-based coloring agents, pyrylium-based coloring agents, squarylium-based coloring agents, triphenylmethane-based coloring agents, cyanine-based coloring agents, and aminium-based coloring agents.

The infrared absorbing coloring agents may be used alone or in combination of two or more kinds thereof.

As the infrared absorbing coloring agent, a coloring agent having a maximum absorption wavelength in the near-infrared region (near-infrared absorbing coloring agent) is preferable.

From the viewpoint that the stretched film has more excellent reverse wavelength dispersibility (hereinafter also simply expressed as follows: “the effect of the present invention is more excellent”), the maximum absorption wavelength of the infrared absorbing coloring agent is preferably positioned in a wavelength range of 700 to 1,200 nm, and more preferably positioned in a wavelength range of 700 to 900 nm.

From the viewpoint that the effect of the present invention is more excellent, an integrated value of the absorbances in a wavelength range of 700 to 900 nm of the infrared absorbing coloring agent is preferably larger than an integrated value of the absorbances in a wavelength range of 400 to 700 nm of the infrared absorbing coloring agent.

The integrated value of the absorbances is a value obtained by summing the absorbances at the respective wavelengths ranging from X to Y nm.

The measurement can be carried out using a spectrophotometer (MPC-3100 manufactured by SHIMADZU Corporation).

Furthermore, the infrared absorbing coloring agent is preferably a dichroic coloring agent. Further, the dichroic coloring agent refers to a coloring agent having a property that an absorbance in the long axis direction and an absorbance in the short axis direction in the molecule are different from each other.

The infrared absorbing coloring agent may have a mesogenic group. By incorporating the mesogenic group into the infrared absorbing coloring agent, the infrared absorbing coloring agent can be easily aligned with a polymer (in particular, a reverse wavelength dispersible polymer) which will be described later, and predetermined absorption characteristics can be easily controlled.

The mesogenic group is a functional group which is rigid and has alignment. Examples of the structure of the mesogenic group include a structure in which a plurality of groups selected from the group consisting of an aromatic ring group (an aromatic hydrocarbon ring group and an aromatic heterocyclic group) and an alicyclic group are linked directly or via a linking group (which represents, for example, —O—, —CO—, —C(R⁰)₂—, —CH═CH—, —CH═N—, —N═N—, —C≡C—, —NR⁰—, or a combination thereof (for example, —COO—, —CONR⁰—, —COOCH₂CH₂—, —CONRCH₂CH₂—, —OCOCH═CH—, and —C≡C—C≡C—), in which R⁰ represents a hydrogen atom or an alkyl group having 1 to 6 carbon atoms).

Suitable aspects of the infrared absorbing coloring agent include a compound represented by Formula (1).

The compound represented by Formula (1) has a less absorption in the visible region, and a stretched film thus obtained is further suppressed from being colored. Further, in a case where this compound is used, a fused ring moiety including a nitrogen atom is easily arranged in a direction perpendicular to the slow axis of the formed stretched film.

In particular, in a case where the compound is introduced into the main chain skeleton moiety of the specific polymer by allowing the position of a group represented by R¹⁴ of this compound to serve as a bonding position (in other words, a case where a divalent infrared absorbing coloring agent residue formed by removing each one hydrogen atom in a group represented by two R¹⁴'s is located in the main chain moicty of the polymer), or in a case where the compound includes a group having a mesogenic group, a fused ring moiety is easily arranged in a direction (in other words, the fast axis direction) perpendicular to the slow axis of the stretched film, as described above. In such a case, an absorption in the infrared region (in particular, at a wavelength of 700 to 900 nm) derived from the fused ring moiety is easily obtained in a direction perpendicular to the slow axis of the stretched film, and a stretched film exhibiting desired characteristics is easily obtained.

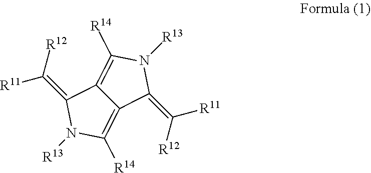

R¹¹ and R¹² each independently represent a hydrogen atom or a substituent, at least one of R¹¹ or R¹² is an electron-withdrawing group, and R¹¹ and R¹² may be bonded to each other to form a ring. Further, as the substituent represented by each of R¹¹ and R¹², a group other than the group having a mesogenic group is preferable.

Examples of the substituent include an alkyl group, an alkenyl group, an alkynyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, an aromatic heterocyclic thio group, a sulfonyl group, a sulfinyl group, a ureide group, a phosphoric acid amide group, a hydroxy group, a mercapto group, a halogen atom, a cyano group, a sulfo group, a carboxyl group, a nitro group, a hydroxamic acid group, a sulfino group, a hydrazino group, an imino group, a heterocyclic group (for example, a heteroaryl group), a silyl group, and a group formed by combination of these groups. Further, the substituent may further be substituted with a substituent.

The electron-withdrawing group represents a substituent whose a Hammett's sigma para value (op value) is positive, and examples thereof include a cyano group, an acyl group, an alkyloxycarbonyl group, an aryloxycarbonyl group, a sulfamoyl group, a sulfinyl group, and a heterocyclic group.

These electron-withdrawing groups may further be substituted.

The Hammett's substituent constant σ value will be described. The Hammett rule is an empirical rule proposed by L. P. Hammett in 1935 in order to quantitatively discuss an influence of a substituent exerted on a reaction or equilibrium of a benzene derivative, and nowadays, its validity has been widely recognized. The substituent constants required for the Hammett rule include a cp value and a am value, and these values are described in many general scientific articles. These are specifically described in, for example, “Lange's Handbook of Chemistry” edited by J. A. Dean, 12^{th} edition, 1979 (McGraw-Hill), “Region of Chemistry”, extra edition, No. 122, pp. 96 to 103, 1979 (Nankodo Co., Ltd.), Chem. Rev., 1991, Vol. 91, pp. 165 to 195, and the like. As the electron-withdrawing group in the embodiment of the present invention, a substituent having a Hammett's substituent constant op value of 0.20 or more is preferable. The op value is preferably 0.25 or more, more preferably 0.30 or more, and still more preferably 0.35 or more. An upper limit thereof is not particularly limited, but is preferably 0.80 or less.

Specific examples thereof include a cyano group (0.66), a carboxyl group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), and an arylsulfonyl group (—SO₂Ph: 0.68).

In the present specification, Me represents a methyl group and Ph represents a phenyl group. Further, the values in parentheses are op values of the representative substituents as extracted from Chem. Rev., 1991, Vol. 91, pp. 165 to 195.

In a case where R¹¹ and R¹² are bonded to form a ring, R¹¹ and R¹² form a 5- to 7-membered ring (preferably a 5- or 6-membered ring), and it is typically preferable to use a ring thus formed as an acidic nucleus in a merocyanine coloring agent.

As the ring formed by the bonding of R¹¹ and R¹², a 1,3-dicarbonyl nucleus, a pyrazolinone nucleus, a 2,4,6-triketohexahydropyrimidine nucleus (including a thioketone form), a 2-thio-2,4-thiazolidinedione nucleus, a 2-thio-2,4-oxazolidinedione nucleus, a 2-thio-2,5-thiazolidinedione nucleus, a 2,4-thiazolidinedione nucleus, a 2,4-imidazolidinedione nucleus, a 2-thio-2,4-imidazolidinedione nucleus, a 2-imidazolin-5-one nucleus, a 3,5-pyrazolidinedione nucleus, a benzothiophen-3-one nucleus, or an indanone nucleus is preferable.

R¹¹ is preferably a heterocyclic group, and more preferably an aromatic heterocyclic group. The heterocyclic group may be either a monocycle or a polycycle. As the heterocyclic group, a pyrazole ring group, a thiazole ring group, an oxazole ring group, an imidazole ring group, an oxadiazole ring group, a thiadiazole ring group, a triazole ring group, a pyridine ring group, a pyridazine ring group, a pyrimidine ring group, a pyrazine ring group, such the benzo-fused ring group (for example, a benzothiazole ring group and a benzopyrazine ring group) or a naphtho-fused ring group, or a composite of these fused rings is preferable.

The heterocyclic group may be substituted with a substituent. Examples of the substituent include the groups exemplified as the substituent represented by each of R¹¹ and R¹².

R¹³'s each independently represent a hydrogen atom, an alkyl group, an aryl group, a heteroaryl group, a substituted boron (—B(Ra)₂, Ra represents a substituent), or a metal atom, or may be covalently bonded or coordinately bonded with R¹¹.

The substituent of the substituted boron represented by R¹³ has the same definition as the above-mentioned substituent for each of R¹¹ and R¹², and is preferably an alkyl group, an aryl group, or a heteroaryl group. The substituent of the substituted boron (for example, the above-mentioned alkyl group, aryl group, or heteroaryl group) may further be substituted with a substituent. Examples of the substituent include the groups exemplified as the substituent represented by each of R¹¹ and R¹².

In addition, the metal atom represented by R¹³ is preferably a transition metal atom, a magnesium atom, an aluminum atom, a calcium atom, a barium atom, a zinc atom, or a tin atom, and more preferably the aluminum atom, the zinc atom, the tin atom, the vanadium atom, the iron atom, the cobalt atom, the nickel atom, the copper atom, the palladium atom, the iridium atom, or the platinum atom.

R¹⁴'s each independently represent an aryl group, a heteroaryl group, or a group having a mesogenic group. The definition of the mesogenic group is the same as mentioned above.

The group having a mesogenic group is preferably a group represented by Formula (2). * represents a bonding position.

*-M¹-(X¹-M²)ₙ-X²—P Formula (2)

M¹ represents a substituted or unsubstituted arylene group, or a substituted or unsubstituted heteroarylene group. Examples of the arylene group include a phenylene group. Examples of the heteroarylene group include a divalent group obtained by removing any two hydrogen atoms from a pyrazole ring, a thiazole ring, an oxazole ring, an imidazole ring, an oxadiazole ring, a thiadiazole ring, a triazole ring, a pyridine ring, a pyridazine ring, a pyrimidine ring, a pyrazine ring, such the benzo-fused ring (for example, a benzothiazole ring and a benzopyrazine ring) or a naphtho-fused ring, or a composite of these fused rings. In a case where the arylene group and the heteroarylene group have a substituent, examples of the substituent include the groups exemplified as the substituent represented by each of R¹¹ and R¹².

X¹ represents a single bond, —O—, —CO—, —C(R⁰)₂—, —CH═CH—, —CH═N—, —N═N—, —C≡C—, —NR⁰—, or a combination thereof (for example, —COO—, —CONR—, —COOCH₂CH₂—, —CONRCH₂CH₂—, —OCOCH═CH—, and —C≡C—C≡C—). R⁰ represents a hydrogen atom or an alkyl group having 1 to 5 carbon atoms.

M² represents a substituted or unsubstituted arylene group, a substituted or unsubstituted heteroarylene group, or a substituted or unsubstituted cycloalkylene group. Examples of the arylene group include a phenylene group. Examples of the heteroarylene group include a divalent group obtained by removing any two hydrogen atoms from a pyrazole ring, a thiazole ring, an oxazole ring, an imidazole ring, an oxadiazole ring, a thiadiazole ring, a triazole ring, a pyridine ring, a pyridazine ring, a pyrimidine ring, a pyrazine ring, such the benzo-fused ring (for example, a benzothiazole ring and a benzopyrazine ring) or a naphtho-fused ring, or a composite of these fused rings. The number of carbon atoms included in the cycloalkylene group is preferably 5 to 7. In a case where the arylene group, the heteroarylene group, and the cycloalkylene group have a substituent, examples of the substituent include the groups exemplified as the substituent represented by each of R¹¹ and R¹².

X² represents a single bond or a divalent linking group. Examples of the divalent linking group include a divalent hydrocarbon group (for example, a divalent aliphatic hydrocarbon group such as an alkylene group having 1 to 10 carbon atoms, an alkenylene group having 1 to 10 carbon atoms, and an alkynylene group having 1 to 10 carbon atoms, and a divalent aromatic hydrocarbon group such as an arylene group), a divalent heterocyclic group, —O—, —S—, —NH—, —N(Q)-, —CO—, or a group formed by combination of these groups (for example, —O-divalent hydrocarbon group-, —(O-divalent hydrocarbon group)ₘ-O— (m represents an integer of 1 or more), and -divalent hydrocarbon group-O—CO—). Q represents a hydrogen atom or an alkyl group.

n represents 1 to 10. Among these, n is preferably 1 to 5, and more preferably 2 to 4.

P represents a hydrogen atom or a polymerizable group. The type of the polymerizable group is not particularly limited, and a polymerizable group which is radically polymerizable or cationically polymerizable is preferable.

A known radically polymerizable group can be used as the radically polymerizable group, and an acryloyl group or a methacryloyl group is preferable.

A known cationically polymerizable group can be used as the cationically polymerizable group, and specific examples thereof include an alicyclic ether group, a cyclic acetal group, a cyclic lactone group, a cyclic thioether group, a spiroorthoester group, and a vinyloxy group. Among those, the alicyclic ether group or the vinyloxy group is preferable, and the epoxy group, the oxetanyl group, or the vinyloxy group is more preferable.

In particular, preferred examples of the polymerizable group include the following groups.

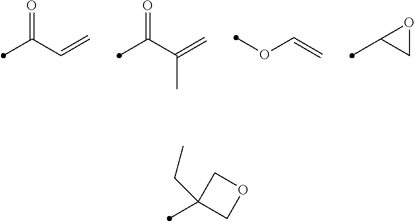

Each of the groups represented by R¹¹ to R¹⁴ may further have a substituent. For example, the aryl group represented by R¹⁴ may further have a substituent. Examples of the substituent include the groups exemplified as the substituent represented by each of R¹¹ and R¹².

The infrared absorbing coloring agent is more preferably a compound represented by Formula (3).

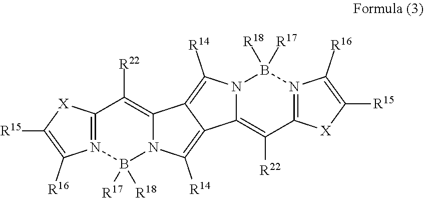

The definition of R⁴ is the same as mentioned above.

R²²'s each independently represent a cyano group, an acyl group, an alkoxycarbonyl group, an alkylsulfinyl group, an arylsulfinyl group, or a nitrogen-containing heteroaryl group.

R¹⁵ and R¹⁶ each independently represent a hydrogen atom, an alkyl group, an alkoxy group, an aryl group, or a heteroaryl group, and R¹⁵ and R¹⁶ may be bonded to each other to form a ring. Examples of the ring thus formed include an alicycle having 5 to 10 carbon atoms, an aromatic hydrocarbon ring having 6 to 10 carbon atoms, and an aromatic heterocyclic ring having 3 to 10 carbon atoms.

The ring formed by the bonding of R¹⁵ and R¹⁶ may further be substituted with a substituent. Examples of the substituent include the groups exemplified in the description of the substituent represented by each of R¹¹ and R¹².

R¹⁷ and R¹⁸ each independently represent an alkyl group, an alkoxy group, an aryl group, or a heteroaryl group. The group represented by each of R¹⁷ and R¹⁸ may further be substituted with a substituent. Examples of the substituent include the groups exemplified in the description of the substituent represented by each of R¹¹ and R¹².

X's each independently represent an oxygen atom, a sulfur atom, —NR—, —CRR′—, —CH═CH—, or —N═CH—, and R and R′ each independently represent a hydrogen atom, an alkyl group, or an aryl group.

The infrared absorbing coloring agent residue may be arranged in the main chain moiety or a side chain moiety in the specific polymer.

Examples of the repeating unit having an infrared absorbing coloring agent residue include a repeating unit represented by Formula (4) and a repeating unit represented by Formula (5).

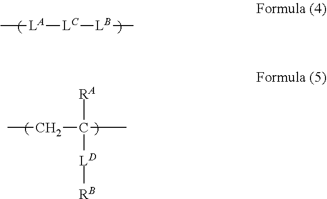

In Formula (4), L^{A} and L^{B} each independently represent a single bond or a divalent linking group. Examples of the divalent linking group include a divalent hydrocarbon group (for example, a divalent aliphatic hydrocarbon group such as an alkylene group, an alkenylene group, and an alkynylene group, and a divalent aromatic hydrocarbon group such as an arylene group), a divalent heterocyclic group, —O—, —S—, —NH—, —N(Q)-, —CO—, or a group formed by combination of these groups (for example, —O-divalent hydrocarbon group-, —O-divalent hydrocarbon group-O—, and —O—CO—). Q represents a hydrogen atom or an alkyl group.

L^{C} represents a divalent infrared absorbing coloring agent residue. As mentioned above, the divalent infrared absorbing coloring agent residue represents a group formed by removing two hydrogen atoms from an infrared absorbing coloring agent. The definition and suitable range of the infrared absorbing coloring agent are the same as mentioned above.

Among those, a group formed by removing two hydrogen atoms from the compound represented by Formula (1) is preferable, and a group represented by Formula (6) is more preferable.

In Formula (6), the definitions of R¹¹ and R¹³ are the same as mentioned above.

In Formula (6), Ar represents an arylene group or a heteroarylene group.

In Formula (6), * represents a bonding position.

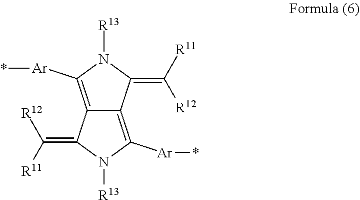

In Formula (5), L^{D} represents a single bond or a divalent linking group. Examples of the divalent linking group include the groups exemplified by the divalent linking group represented by each of L^{A} and L^{B}.

R^{A} represents a hydrogen atom or an alkyl group.

R^{B} represents a monovalent infrared absorbing coloring agent residue. As mentioned above, the monovalent infrared absorbing coloring agent residue represents a group formed by removing one hydrogen atom from the infrared absorbing coloring agent. The definition and suitable range of the infrared absorbing coloring agent are the same as mentioned above. Among these, the group formed by removing one hydrogen atom from the compound represented by Formula (1) is preferable.

The content of the repeating unit having an infrared absorbing coloring agent residue included in the specific polymer is not particularly limited, but is preferably 1% to 50% by mole, and more preferably 5% to 40% by mole with respect to all the repeating units from the viewpoint that the effect of the present invention is more excellent.

The specific polymer may include a repeating unit other than the repeating unit having the infrared absorbing coloring agent residue.

The specific polymer may include a repeating unit having a fluorene structure, and may include one or more oligofluorene units from the group consisting of a repeating unit represented by Formula (7) and a repeating unit represented by Formula (8).

In a case where the specific polymer includes the oligofluorene unit, the reverse wavelength dispersibility of the stretched film including the specific polymer is more excellent.

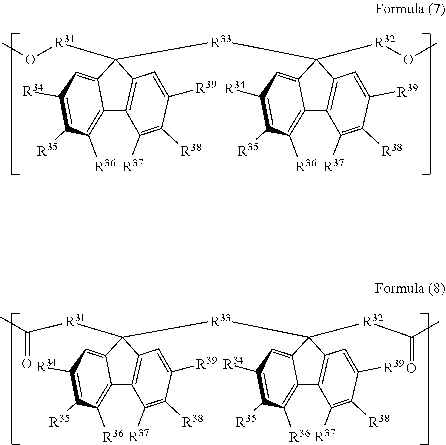

In Formulae (7) and (8), R³¹ to R³³ each independently represent a single bond, or an alkylene group having 1 to 4 carbon atoms, which may have a substituent.

R³⁴ to R³⁹ each independently represent a hydrogen atom, an alkyl group having 1 to 10 carbon atoms, which may have a substituent, an aryl group having 4 to 10 carbon atoms, which may have a substituent, a heteroaryl group having 4 to 10 carbon atoms, which may have a substituent, an acyl group having 1 to 10 carbon atoms, which may have a substituent, an alkoxy group having 1 to 10 carbon atoms, which may have a substituent, an aryloxy group having 1 to 10 carbon atoms, which may have a substituent, an acyloxy group having 1 to 10 carbon atoms, which may have a substituent, an amino group which may have a substituent, a vinyl group having 1 to 10 carbon atoms, which may have a substituent, an ethynyl group having 1 to 10 carbon atoms, which may have a substituent, a sulfur atom having a substituent, a silicon atom having a substituent, a halogen atom, a nitro group, or a cyano group. It should be noted that at least two adjacent groups of R³⁴, . . . , or R³⁹ may be bonded to each other to form a ring.

Examples of the substituent include the groups exemplified as the substituent represented by each of R¹¹ and R¹² in Formula (1).

In addition, each two of R³⁴'s, R³⁵'s, R³⁶'s, R³⁷'s, R³⁸'s, and R³⁹'s included in Formula (7) may be the same as or different from each other. Similarly, each two of R³⁴'s, R³⁵'s, R³⁶'s, R³⁷'s, R³⁸'s, and R³⁹'s included in Formula (8) may be the same as or different from each other.

Examples of the alkylene group having 1 to 4 carbon atoms, which may have a substituent, include the following alkylene groups.

Linear alkylene groups such as a methylene group, an ethylene group, an n-propylene group, and an n-butylene group; and alkylene groups having a branched chain, such as a methylmethylene group, a dimethylmethylene group, an ethylmethylene group, a propylmethylene group, a (1-methylethyl) methylene group, a 1-methylethylene group, a 2-methylethylene group, a 1-ethylethylene group, a 2-ethylethylene group, a 1-methylpropylene group, a 2-methylpropylene group, a 1,1-dimethylethylene group, a 2,2-dimethylpropylene group, and a 3-methylpropylene group.

As the alkylene group having 1 to 4 carbon atoms, represented by each of R³¹ and R³², an alkylene group having 2 or 3 carbon atoms is preferable.

As the alkylene group having 1 to 4 carbon atoms represented by R³³, an alkylene group having 1 or 2 carbon atoms is preferable.

As the alkyl group having 1 to 10 carbon atoms, which may have a substituent, an alkyl group having 1 to 4 carbon atoms is preferable, and an alkyl group having 1 or 2 carbon atoms is preferable.

As the aryl group having 4 to 10 carbon atoms, which may have a substituent, an aryl group having 4 to 8 carbon atoms is preferable, and an aryl group having 4 to 7 carbon atoms is more preferable.

As the heteroaryl group having 4 to 10 carbon atoms, which may have a substituent, a heteroaryl group having 4 to 8 carbon atoms is preferable, and a heteroaryl group having 4 to 7 carbon atoms is more preferable.

As the acyl group having 1 to 10 carbon atoms, which may have a substituent, an acyl group having 1 to 4 carbon atoms is preferable, and an acyl group having 1 or 2 carbon atoms is more preferable.

As the alkoxy group or aryloxy group having 1 to 10 carbon atoms, which may have a substituent, an alkoxy group or aryloxy group having 1 to 4 carbon atoms is preferable, and an alkoxy group or aryloxy group having 1 or 2 carbon atoms is more preferable.

As the acyloxy group having 1 to 10 carbon atoms, which may have a substituent, an acyloxy group having 1 to 4 carbon atoms is preferable, and an acyloxy group having 1 or 2 carbon atoms is more preferable.

As the vinyl group or ethynyl group having 1 to 10 carbon atoms, which may have a substituent, a vinyl group or ethynyl group having 1 to 4 carbon atoms is preferable.

Examples of the silicon atom having a substituent include trialkylsilyl groups such as a trimethylsilyl group and a triethylsilyl group, and trialkoxysilyl groups such as a trimethoxysilyl group and a triethoxysilyl group.

The content of the oligofluorene unit included in the specific polymer is not particularly limited, but is preferably 1% to 70% by mole, and more preferably 10% to 40% by mole with respect to all the repeating units from the viewpoint that the effect of the present invention is more excellent.

In a case where the specific polymer includes the oligofluorene unit, the specific polymer is preferably a polycarbonate, a polyester, or a polyester carbonate.

That is, in a case where the specific polymer includes the oligofluorene unit, the specific polymer preferably includes at least one of a carbonate bond or an ester bond. Further, the ether group (—O—) described in Formula (7) and the carbonyl group (—CO—) described in Formula (8) may form a part of a carbonate bond and an ester bond.

In a case where the specific polymer is the polycarbonate, the polyester, or the polyester carbonate, the specific polymer may include a repeating unit derived from a dihydroxy compound and a repeating unit derived from a diester compound.

For example, the specific polymer may include a repeating unit represented by Formula (X).

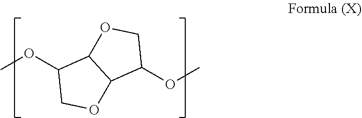

Examples of the dihydroxy compound into which the repeating unit represented by Formula (X) can be introduced include isosorbide, isomannide, and isoidide, which have a stereoisomeric relationship with one another.

The content of the repeating unit represented by Formula (X) included in the specific polymer is not particularly limited, but is preferably 5% to 70% by mole, and more preferably 10% to 65% by mole with respect to all the repeating units from the viewpoint that the effect of the present invention is more excellent.

The specific polymer may include a repeating unit represented by the following Formula (Y).

—(O-L^{E}-O)— Formula (Y)

L^{E} represents an alkylene group having 2 to 20 carbon atoms, which may have a substituent, a cycloalkylene group having 4 to 20 carbon atoms, which may have a substituent, a group having an acetal ring having 2 to 20 carbon atoms, which may have a substituent, a group represented by Formula (Z), or a group represented by Formula (V).

—CH_{Z}-cycloalkylene group-CH²— Formula (Z)

-(L^{F}-O)ₚ-L^{F}- Formula (V)

L^{F} represents an alkylene group having 2 to 10 carbon atoms, which may have a substituent, and p represents an integer of 1 to 40.

The content of the repeating unit represented by Formula (Y) included in the specific polymer is not particularly limited, but is preferably 1% to 40% by mole, and more preferably 5% to 30%/a by mole with respect to all the repeating units from the viewpoint that the effect of the present invention is more excellent.

The specific polymer may include one or more selected from the group consisting of a repeating unit represented by Formula (9) and a repeating unit represented by Formula (11).

In a case where the specific polymer includes the repeating unit represented by Formula (9), the reverse wavelength dispersibility of a stretched film including the specific polymer is more excellent.

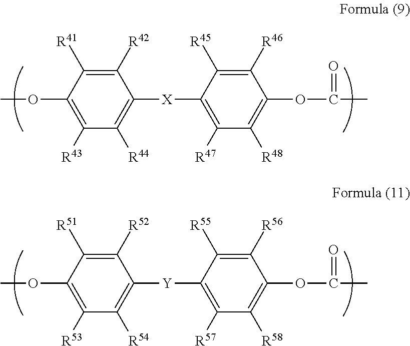

In Formula (9), R⁴¹ to R⁴⁸ each independently represent a hydrogen atom, a halogen atom, or a hydrocarbon group having 1 to 6 carbon atoms.

X represents a group represented by Formula (10). In Formula (10), * represents a bonding position.

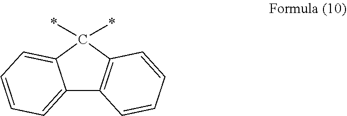 [SMILES: *C1(*)c2ccccc2-c2ccccc21]

In Formula (11), R⁵¹ to R⁵⁸ each independently represent a hydrogen atom, a halogen atom, or a hydrocarbon group having 1 to 22 carbon atoms.

Y represents —C(R⁶¹)(R⁶²)—, a group represented by Formula (12), —Si(R⁶⁷(R⁶⁸)—, —SO₂—, —S—, a divalent aliphatic hydrocarbon group, —C(CH₃)₂-phenylene group-C(CH₃)₂—, or —CO—O-L-O—CO—.

In Formula (12), * represents a bonding position.

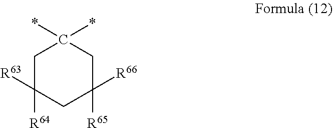

R⁶¹, R⁶², R⁶⁷, and R⁶⁸ each independently represent a hydrogen atom, a halogen atom, or a hydrocarbon group having 1 to 22 carbon atoms (for example, an aryl group having 6 to 10 carbon atoms).

R⁶³ to R⁶⁶ each independently represent a hydrogen atom or an alkyl group.

L represents a divalent aliphatic hydrocarbon group.

The content of the repeating unit represented by Formula (9) in the specific polymer is not particularly limited, but is preferably 20% to 80% by mole with respect to all the repeating units.

The content of the repeating unit represented by Formula (11) in the specific polymer is not particularly limited, but is preferably 5% to 60% by mole with respect to all the repeating units.

A method for producing the specific polymer is not particularly limited, and a known method can be applied. For example, in a case where the specific polymer is the polycarbonate, the polyester, or the polyester carbonate, examples of the method include a solution polymerization method or interfacial polymerization method, using a phosgene or a carboxylic acid halide, and a melt polymerization method in which a reaction is carried out without using a solvent.

In a case where the stretched film includes the specific polymer, it may include another material.

For example, the stretched film including the specific polymer may include another polymer. In particular, the stretched film may include a polymer include no repeating unit having an infrared absorbing coloring agent residue.

As the other polymer, a so-called reverse wavelength dispersible polymer is preferable.

The reverse wavelength dispersible polymer means a polymer which is used to form an optically anisotropic film exhibiting reverse wavelength dispersibility.

One of suitable aspects of the other polymer may be a polymer (hereinafter also referred to as a “first polymer”) including one or more oligofluorene units selected from the group consisting of a repeating unit represented by Formula (7) and a repeating unit represented by Formula (8).

The first polymer is preferably a polycarbonate, a polyester, or a polyester carbonate. In a case where the first polymer includes an oligofluorene unit, the first polymer preferably includes at least one of a carbonate bond or an ester bond. Further, the ether group (—O—) described in Formula (7) and the carbonyl group (—CO—) described in Formula (8) may form a part of a carbonate bond and an ester bond.

In addition, the first polymer may include a repeating unit selected from the group consisting of the unit represented by Formula (X) and the unit represented by Formula (Y).

Other suitable aspects of the other polymer include a polymer including the repeating unit of Formula (9) and the repeating unit of Formula (11).

In addition, other suitable aspects of the other polymer include cellulose acylate.

As the cellulose acylate, a lower fatty acid ester of cellulose is preferable. The lower fatty acid means a fatty acid having 6 or less carbon atoms. The fatty acid preferably has 2 carbon atoms (cellulose acetate), 3 carbon atoms (cellulose propionate), or 4 carbon atoms (cellulose butyrate). In addition, mixed fatty acid esters such as cellulose acetate propionate and cellulose acetate butyrate may be used.

The acetylation degree of cellulose acetate is preferably 55.0% to 62.5%, more preferably 57.0% to 62.0%, and still more preferably 58.5% to 61.5%.

The acetylation degree means an amount of bonded acetic acid per unit mass of cellulose. The acetylation degree follows the measurement and computation of the acetylation degree in ASTM: D-817-91 (a test method for cellulose acetate and the like).

Furthermore, in a case where cellulose acylate is used as the other polymer, additives such as a plasticizer, a deterioration inhibitor, a retardation enhancer, and an ultraviolet absorber may be used in combination.

Examples of the additive include those exemplified in JP2004-050516A.

A method for producing a stretched film including the specific polymer is not particularly limited, but examples thereof include a method in which an unstretched film is formed using a composition including a specific polymer, and the obtained unstretched film is stretch-aligned to form a stretched film that is an optically anisotropic film.

Examples of the method for forming an unstretched film include a method in which a composition including a specific polymer, a solvent, and other materials added as needed (for example, the other polymer described above) is applied, and then the solvent is removed to form an unstretched film and a method in which a solid content including a specific polymer without using a solvent is molten to prepare a film.

Examples of the stretching method include known methods such as longitudinal uniaxial stretching, horizontal uniaxial stretching, or a combination thereof such as simultaneous biaxial stretching or sequential biaxial stretching.

Furthermore, the solvent in the composition used in production of the unstretched film is not particularly limited, but an organic solvent is preferable. Examples of the organic solvent include an amide (for example, N,N-dimethylformamide), a sulfoxide (for example, dimethyl sulfoxide), a heterocyclic compound (for example, pyridine), a hydrocarbon (for example, benzene and hexane), an alkyl halide (for example, chloroform and dichloromethane), an ester (for example, methyl acetate, ethyl acetate, and butyl acetate), a ketone (for example, acetone and methyl ethyl ketone), and an ether (for example, tetrahydrofuran and 1,2-dimethoxyethane). In addition, two or more kinds of the organic solvents may be used in combination.

<Suitable Aspect 2>

Other suitable aspects of the stretched film include a stretched film including an infrared absorbing coloring agent and a polymer.

The definition of the infrared absorbing coloring agent is as described in <Suitable Aspect 1> mentioned above. As the infrared absorbing coloring agent, a compound represented by Formula (1) is preferable.

The type of the polymer is not particularly limited, but examples of the polymer include a reverse wavelength dispersible polymer.

Examples of the polymer (for example, a reverse wavelength dispersible polymer) include the polymers exemplified as the other polymer described in <Suitable Aspect 1> mentioned above.

The content of the infrared absorbing coloring agent in the stretched film is not particularly limited, but from the viewpoint that the effect of the present invention is more excellent, the content is preferably 1% to 30% by mass, and more preferably 3% to 20% by mass with respect to the total mass of the stretched film.

The content of the polymer in the stretched film is not particularly limited, but from the viewpoint that the effect of the present invention is more excellent, the content is preferably 60% to 99% by mass, and more preferably 70% to 97% by mass with respect to the total mass of the stretched film.

A method for producing a stretched film including the infrared absorbing coloring agent and the polymer is not particularly limited, but examples thereof include a method in which an unstretched film is formed using a composition including an infrared absorbing coloring agent and a polymer, and the obtained unstretched film is stretch-aligned to form a stretched film that is an optically anisotropic film.

Examples of the method for forming an unstretched film include a method in which a composition including an infrared absorbing coloring agent, a polymer, and a solvent is applied, and then the solvent is removed to form an unstretched film, and a method in which a solid content including an infrared absorbing coloring agent and a polymer is molten without using a solvent to prepare a film.

Examples of the stretching method include known methods such as longitudinal uniaxial stretching, horizontal uniaxial stretching, or a combination thereof such as simultaneous biaxial stretching or sequential biaxial stretching.

Furthermore, the solvent in the composition used in production of the unstretched film is not particularly limited, but an organic solvent is preferable. Examples of the organic solvent include those exemplified as the organic solvent described in <Suitable Aspect 1> mentioned above.

<Uses>

The above-mentioned stretched film can be applied to various uses, and it can also be used as, for example, a so-called λ/4 plate or λ/2 plate by adjusting the in-plane retardation of the stretched film.

Furthermore, the λ/4 plate is a plate having a function of converting linearly polarized light having a specific wavelength into circularly polarized light (or converting circularly polarized light into linearly polarized light). More specifically, the λ/4 plate is a plate in which an in-plane retardation Re at a predetermined wavelength of λ nm is λ/4 (or an odd number of times thereof).

The in-plane retardation (Re(550)) of the λ/4 plate at a wavelength of 550 nm may have an error of about 25 nm from an ideal value (137.5 nm) at a center, and is, for example, preferably 110 to 160 nm, and more preferably 120 to 150 nm.

In addition, the λ/2 plate is an optically anisotropic film in which the in-plane retardation Re(λ) at a specific wavelength of λ nm satisfies Re(λ)≈λ/2. This formula only needs to be satisfied at any wavelength (for example, 550 nm) in the visible region. Above all, it is preferable that the in-plane retardation Re(550) at a wavelength of 550 nm satisfies the following relationship.

210 nm≤Re(550)≤300 nm

A stretched film and an optical film including the stretched film may be included in a display device. That is, examples of more specific uses of the stretched film include an optical compensation film for optical compensation of a liquid crystal cell, and an antireflection film for use in a display device such as an organic electroluminescence display device.

Among those, preferred aspects of the optical film include a circularly polarizing plate including a stretched film and a polarizer. This circularly polarizing plate can be suitably used as the antireflection film. That is, it is possible to further suppress a reflection tint in a display device including a display element (for example, an organic electroluminescence display element) and a circularly polarizing plate arranged on the display element.

In addition, the stretched film is suitably used in an optical compensation film of an in plane switching (IPS) type liquid crystal display device, and can improve a tint change as viewed from a tilt direction and a light leakage upon black display.

Examples of the optical film including a stretched film include a circularly polarizing plate including a polarizer and a stretched film, as described above.

The polarizer only needs to be a member (linear polarizer) having a function of converting light into specific linearly polarized light, and an absorptive type polarizer can be usually used.

Examples of the absorptive type polarizer include an iodine-based polarizer, a dye-based polarizer using a dichroic dye, and a polyene-based polarizer. The iodine-based polarizer and the dye-based polarizer are classified into a coating type polarizer and a stretching type polarizer, both of which can be applied, but a polarizer which is manufactured by allowing polyvinyl alcohol to adsorb iodine or a dichroic dye and performing stretching is preferable.

A relationship between the absorption axis of the polarizer and the slow axis of the stretched film is not particularly limited, but in a case where the stretched film is a λ/4 plate and the optical film is used as a circularly polarizing film, an angle formed between the absorption axis of the polarizer and the slow axis of the stretched film is preferably 45°±10°.

### EXAMPLES

Hereinafter, the features of the present invention will be described in more details with reference to Examples and Comparative Examples. The materials, the amounts of materials used, the proportions, the treatment details, the treatment procedure, and the like shown in Examples below can be appropriately modified as long as the modifications do not depart from the spirit of the present invention. Therefore, the scope of the present invention should not be construed as being limited to specific examples shown below.

### Example 1

An aqueous sodium hydroxide solution and ion exchange water were charged into a reaction vessel, and a monomer A, a monomer B, and an IR coloring agent monomer 1, each shown below, were further dissolved in the reaction vessel at a molar ratio of 27:63:10, and a small amount of hydrosulfite was further added thereto.

Next, methylene chloride was added to the reaction vessel, and then phosgene was blown at 20° C. over about 60 minutes. Further, p-tert-butylphenol was added to the reaction vessel to perform emulsification, triethylamine was added thereto, and the mixture was stirred at 30° C. for about 3 hours to terminate the reaction.

After completion of the reaction, the organic phase was separated and methylene chloride was evaporated to obtain a polycarbonate copolymer. The compositional ratio of each repeating unit in the obtained polycarbonate copolymer was almost the same as the amount ratio of the monomer charged.

The obtained polycarbonate copolymer was dissolved in methylene chloride to prepare a dope solution having a concentration of solid contents of 15% by mass. A cast film was manufactured from this dope solution and uniaxially stretched 1.7 times with free width at a temperature of 210° C. to obtain a stretched film.

The optical characteristics of the obtained stretched film were measured, and it was thus found that Re(550) was 142 nm, Re(450)/Re(550) was 0.84, and Re(650)/Re(550) was 1.11.

In addition, absorptions in the infrared region were confirmed using a spectrophotometer (MPC-3100 (manufactured by SHIMADZU Corporation)) equipped with a polarizer for infrared rays, and it was thus confirmed that the absorption in the direction in parallel with the fast axis of the stretched film was larger than the absorption in the direction in parallel with the slow axis at a wavelength of 700 to 900 nm.

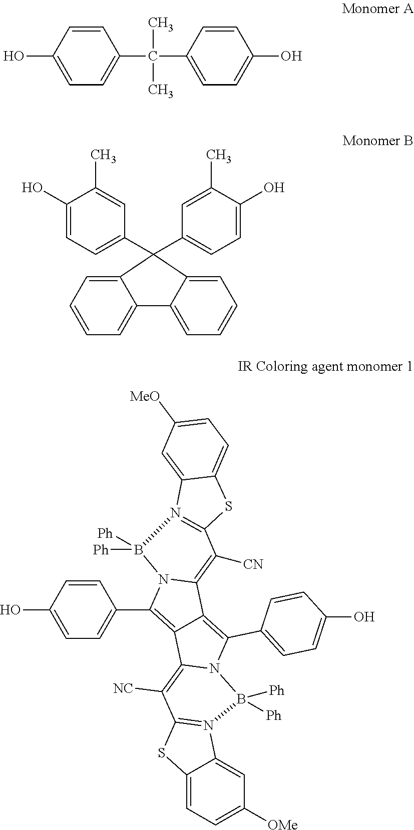

### Example 2

A monomer C shown below (35 parts by mass), isosorbide (40 parts by mass), 1,4-cyclohexanedimethanol (cis-trans mixture) (15 parts by mass), diphenyl carbonate (95 parts by mass), an IR coloring agent monomer 2 shown below (20 parts by mass), and calcium acetate monohydrate (4×10⁻⁴ parts by mass) were put into a reaction vessel, and the inside of a reaction apparatus was substituted with nitrogen under reduced pressure. Under a nitrogen atmosphere, the temperature was raised to 220° C. over 60 minutes, and the reaction was carried out at normal pressure for 60 minutes. Then, the pressure was reduced from normal pressure over 90 minutes and held for 30 minutes, and a phenol thus generated was extracted from the reaction system.

Then, while raising the temperature of a heat medium to 240° C. over 15 minutes, the pressure was reduced to 0.10 kPa or less, and a phenol thus generated was extracted from the reaction system. The pressure was restored to normal pressure with nitrogen to stop the reaction, thereby obtaining a polycarbonate copolymer.

The obtained copolymer was dissolved in methylene chloride to prepare a dope solution having a concentration of solid contents of 15% by mass. A cast film was manufactured from this dope solution and uniaxially stretched 2.3 times with free width at a temperature of 170° C. to obtain a stretched film.

The optical characteristics of the obtained stretched film were measured, and it was thus found that Re(550) was 144 nm, Re(450)/Re(550) was 0.88, and Re(650)/Re(550) was 1.13.

In addition, absorptions in the infrared region were confirmed using a spectrophotometer (MPC-3100 (manufactured by SHIMADZU Corporation)) equipped with a polarizer for infrared rays, and it was thus confirmed that the absorption in the direction in parallel with the fast axis of the stretched film was larger than the absorption in the direction in parallel with the slow axis at a wavelength of 700 to 900 nm.

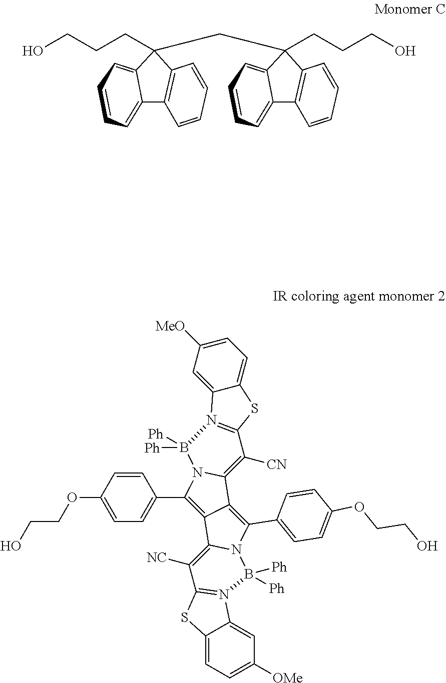

### Example 3

An aqueous sodium hydroxide solution and ion exchange water were charged into a reaction vessel, the monomer A and the monomer B were dissolved in the reaction vessel at a molar ratio of 32:68, and a small amount of hydrosulfite was added thereto.

Next, methylene chloride was added to the reaction vessel, and then phosgene was blown at 20° C. over about 60 minutes. Further, p-tert-butylphenol was added to the reaction vessel to perform emulsification, triethylamine was added thereto, and the mixture was stirred at 30° C. for about 3 hours to terminate the reaction.

After completion of the reaction, the organic phase was separated and methylene chloride was evaporated to obtain a polycarbonate copolymer A. The compositional ratio of each repeating unit in the obtained polycarbonate copolymer A was almost the same as the amount ratio of the monomer charged.

Next, an aqueous sodium hydroxide solution and ion exchange water were charged into another reaction vessel, the monomer A and the IR coloring agent monomer 1 were dissolved therein at a molar ratio of 55:45, and a small amount of hydrosulfite was added thereto.

Next, methylene chloride was added to the reaction vessel, and then phosgene was blown at 20° C. over about 60 minutes. Further, p-tert-butylphenol was added to the reaction vessel to perform emulsification, triethylamine was added thereto, and the mixture was stirred at 30° C. for about 3 hours to terminate the reaction.

After completion of the reaction, the organic phase was separated and methylene chloride was evaporated to obtain a polycarbonate copolymer B. The compositional ratio of each repeating unit in the obtained polycarbonate copolymer B was almost the same as the amount ratio of the monomer charged.

The obtained polycarbonate copolymer A and polycarbonate copolymer B were dissolved at a mass ratio of 70:30 in methylene chloride to prepare a dope solution having a concentration of solid contents of 15% by mass. A cast film was manufactured from this dope solution and uniaxially stretched 1.8 times with free width at a temperature of 210° C. to obtain a stretched film.

The optical characteristics of the obtained stretched film were measured, and it was thus found that Re(550) was 142 nm, Re(450)/Re(550) was 0.87, and Re(650)/Re(550) was 1.10.

In addition, absorptions in the infrared region were confirmed using a spectrophotometer (MPC-3100 (manufactured by SHIMADZU Corporation)) equipped with a polarizer for infrared rays, and it was thus confirmed that the absorption in the direction in parallel with the fast axis of the stretched film was larger than the absorption in the direction in parallel with the slow axis at a wavelength of 700 to 900 nm.

### Example 4

The polycarbonate copolymer A prepared in Example 3 and the following IR compound 1 were dissolved at a mass ratio of 95:5 in methylene chloride to prepare a dope solution having a concentration of solid contents of 15% by mass. A cast film was manufactured from this dope solution and uniaxially stretched 1.8 times with free width at a temperature of 210° C. to obtain a stretched film.

The optical characteristics of the obtained stretched film were measured, and it was thus found that Re(550) was 140 nm, Re(450)/Re(550) was 0.82, and Re(650)/Re(550) was 1.10.

In addition, absorptions in the infrared region were confirmed using a spectrophotometer (MPC-3100 (manufactured by SHIMADZU Corporation)) equipped with a polarizer for infrared rays, and it was thus confirmed that the absorption in the direction in parallel with the fast axis of the stretched film was larger than the absorption in the direction in parallel with the slow axis at a wavelength of 700 to 900 nm.

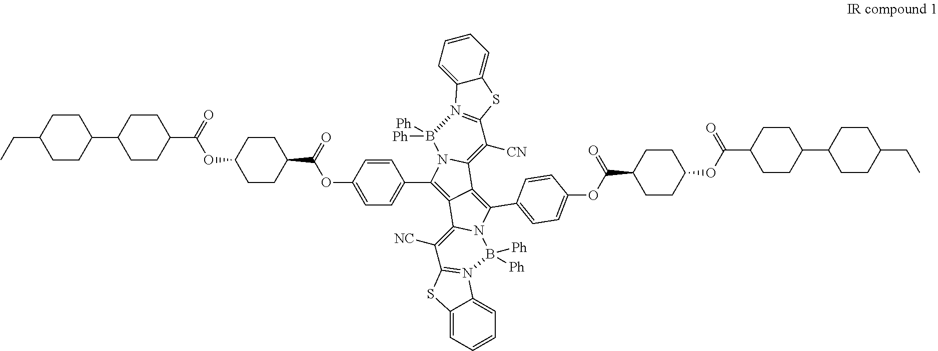

The results are shown in Table 1.

TABLE 1

| | Re(550) (nm) | Re(450)/Re(550) | Re(650)/Re(550) |
|---|---|---|---|
| Example 1 | 142 | 0.84 | 1.11 |
| Example 2 | 144 | 0.88 | 1.13 |
| Example 3 | 142 | 0.87 | 1.10 |
| Example 4 | 140 | 0.82 | 1.10 |

As shown in the table, it was confirmed that the desired effect can be obtained with the stretched film of the embodiment of the present invention.

<Manufacture of Organic EL Display Device>

A polyvinyl alcohol film having a thickness of 80 μm was dyed by immersing the film in an aqueous iodine solution at an iodine concentration of 0.05% by mass at 30° C. for 60 seconds. Subsequently, the obtained film was vertically stretched five times its original length while the film was immersed in an aqueous boric acid solution (boric acid concentration: 4% by mass) for 60 seconds, and then the vertically stretched film was dried at 50° C. for 4 minutes to obtain a polarizer having a thickness of 20 μm.

A commercially available cellulose acylate-based film “TD80UL” (manufactured by FUJIFILM Corporation) was prepared and immersed in an aqueous sodium hydroxide solution at 1.5 mol/liter at 55° C., and then the obtained film was sufficiently washed with water to remove sodium hydroxide.

Thereafter, the obtained film was immersed in a diluted aqueous sulfuric acid solution at 0.005 mol/liter at 35° C. for one minute, then the obtained film was immersed in water, and the diluted aqueous sulfuric acid solution on the film was sufficiently washed off. Thereafter, the washed film was dried at 120° C. to manufacture a protective film for a polarizer.

The protective film for a polarizer manufactured above was bonded to one surface of the polarizer manufactured above with a polyvinyl alcohol-based adhesive to manufacture a polarizing plate including the polarizer and the protective film for a polarizer arranged on one surface of the polarizer.

A pressure sensitive adhesive (SK-2057, manufactured by Soken Chemical & Engineering Co., Ltd.) was applied onto the polarizer (having no protective film for a polarizer) side in the polarizing plate manufactured above to form a pressure sensitive adhesive layer, and the stretched film manufactured in Example 1 was bonded thereto such that the pressure sensitive adhesive layer and the stretched film were adhered to each other, thereby manufacturing a circularly polarizing plate. In addition, the angle formed between the slow axis of the stretched film and the transmission axis of the polarizer was set to 45°.

Galaxy S4 (manufactured by Samsung) was disintegrated and a part of an antireflection film bonded to the product was peeled and used as a light emitting layer. The circularly polarizing plate manufactured above was bonded to the light emitting layer via a pressure sensitive adhesive while preventing air permeation, thereby manufacturing an organic electroluminescence (EL) display device.

In addition, an organic E display device was manufactured using the stretched films manufactured in Examples 2 to 4, instead of the stretched film manufactured in Example 1.

What is claimed is:

1. A stretched film having a slow axis in an in-plane direction,
wherein the stretched film satisfies a relationship of Formula (A), and
an absorption at a wavelength of 700 to 900 mu in a fast axis direction of the stretched film is larger than an absorption at a wavelength of 700 to 900 mu in a slow axis direction of the stretched film,
Re(450)/Re(550)<1.00 Formula (A)
in the formula, Re(450) represents an in-plane retardation of the stretched film at a wavelength of 450 nm and Re(550) represents an in-plane retardation of the stretched film at a wavelength of 550 nm.

2. The stretched film according to claim 1, comprising:
a polymer including a repeating unit having a residue derived from an infrared absorbing coloring agent; or
an infrared absorbing coloring agent and a polymer.

3. The stretched film according to claim 1,
wherein the infrared absorbing coloring agent is a compound represented h Formula (1), 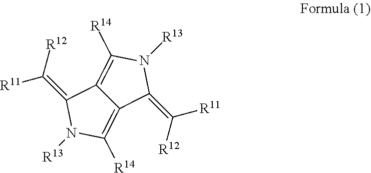
in the formula, R¹¹ and R¹² each independently represent a hydrogen atom or a substituent, at least one of R₁₁ or R¹² is an electron-withdrawing group, and R¹¹ and R¹² may be bonded to each other to form a ring, R¹³'s each independently represent a hydrogen atom, an alkyl group, an aryl group, a heteroaryl group, a substitutional boron, or a metal atom, and may be covalently bonded or coordinately bonded with R¹¹, and R¹⁴'s each independently represent an aryl group, a heteroaryl group, or a group having a mesogenic group.

4. The stretched film according to claim 1,
wherein an in-plane retardation at a wavelength of 550 nm is 110 to 160 nm.

5. A circularly polarizing plate comprising:
the stretched film according to claim 4; and
a polarizer.

6. A display device comprising:
a display element; and
the circularly polarizing plate according to claim 5, arranged on the display element.

7. The stretched film according to claim 2,
wherein the infrared absorbing coloring agent is a compound represented by Formula (1), 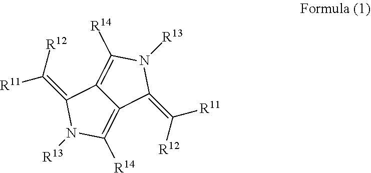
in the formula, R¹¹ and R¹² each independently represent a hydrogen atom or a substituent, at least one of R¹¹ or R¹² is an electron-withdrawing group, and R¹¹ and R¹² may be bonded to each other to form a ring, R's each independently represent a hydrogen atom, an alkyl group, an aryl group, a heteroaryl group, a substitutional boron, or a metal atom, and may be covalently bonded or coordinately bonded with R¹¹, and R¹⁴'s each independently represent an aryl group, a heteroaryl group, or a group having a mesogenic group.

8. The stretched film according to claim 2,
wherein an in-plane retardation at a wavelength of 550 nm is 110 to 160 nm.

9. A circularly polarizing plate comprising:
the stretched film according to claim 8; and
a polarizer.

10. A display device comprising:
a display element; and
the circularly polarizing plate according to claim 9, arranged on the display element.

11. The stretched film according to claim 3,
wherein an in-plane retardation at a wavelength of 550 nm is 110 to 160 am.

12. A circularly polarizing plate comprising:
the stretched film according to claim 11; and
a polarizer.

13. A display device comprising:
a display element; and
the circularly polarizing plate according to claim 12, arranged on the display element.
